(19) United States
(12) Patent Application Publication
(10) Pub. No.: US 2023/0245922 A1
(43) Pub. Date: Aug. 3, 2023

(54) METHODS FOR SIMULTANEOUS GENERATION OF A TRAP-RICH LAYER AND A BOX LAYER

(71) Applicant: pSemi Corporation, San Diego, CA (US)

(72) Inventors: Sebastien KOUASSI, San Diego, CA (US); Sinan GOKTEPELI, Austin, TX (US)

(21) Appl. No.: 18/153,039

(22) Filed: Jan. 11, 2023

Related U.S. Application Data
(60) Provisional application No. 63/300,143, filed on Jan. 17, 2022.

(51) Int. Cl. H01L 21/762; H01L 21/02

(52) U.S. Cl. CPC H01L 21/76243; H01L 21/02323; H01L 23/66

(57) ABSTRACT

Methods for simultaneous generation of a buried oxide (BOX) layer and a trap-rich layer in a silicon substrate are presented. According to one aspect, oxygen is implanted in the silicon substrate such as to form a region of oxygen concentration according to a concentration profile with a peak at a target depth of the BOX layer. According to another aspect, the concentration profile includes a leading-edge profile that is shorter than a trailing-edge profile. According to another aspect, the substrate is annealed to form the BOX layer and a damaged layer immediately below the BOX layer, the damaged layer having a functionality of a trap-rich layer.

### CROSS REFERNCE TO RELATED APPLICATIONS

The present application claims priority to and the benefit of co-pending U.S. Provisional Pat. Application Serial No. 63/300,143 entitled “Methods for Simultaneous Generation of a Trap-Rich Layer and a BOX Layer”, filed on Jan. 17, 2022, the disclosure of which is incorporated herein by reference in its entirety.

### TECHNICAL FIELD

The present disclosure is related to semiconductor technology, and more particularly to generation of a silicon-on-insulator (SOI) substrate including a trap-rich layer that is formed underneath the buried oxide (BOX) layer.

### BACKGROUND

FIG. 1A shows an SOI substrate (100A) that includes a thin layer of silicon (Si, 110) overlying an insulating BOX layer (120). In some cases, performance of RF devices (e.g., transistors) formed in the thin layer of silicon (110) may be affected by the well-known in the art parasitic surface conduction (PSC) effect at the interface between the BOX layer (120) and the bulk substrate (150) that is due to the capacitor-like configuration a SOI stack creates. Provision of a trap-rich layer (130) between the BOX layer and the bulk substrate (150) as shown in the SOI substrate (100B) of FIG. 1B may reduce the PSC effect and therefore increase performance of the RF devices. As known to a person skilled in the art, presence of the trap-rich layer (130) may produce a trap-rich effect that includes trapping of free charges (e.g., electrons, carriers) underneath the BOX layer (120), thereby preventing flow of current that may produce coupling of signals to/between the RF devices formed in the thin layer of silicon (110). Teachings according to the present disclosure describe methods for simultaneous generation of the BOX layer (120) and the trap-rich layer (130) in a single substrate (e.g., bulk silicon substrate 150).

### SUMMARY

According to a first aspect of the present disclosure, a method for simultaneous generation of a buried oxide (BOX) layer and a trap-rich (TR) layer in a silicon substrate is presented, the method comprising: providing a silicon substrate; implanting oxygen into the silicon substrate; based on the implanting, producing an implantation concentration profile that includes: a peak at a target depth of the silicon substrate that corresponds to a region of the BOX layer; a leading-edge that extends from a region of the silicon substrate proximal a surface of said substrate to the peak; and a trailing edge that extends from the peak to a region of the silicon substrate distal the surface of the silicon substrate; and annealing the silicon substrate thereby simultaneously generating: the BOX layer in a region about the peak, and a first damaged layer in a region below the BOX layer that extends along the trailing edge, the first damaged layer providing functionality of the TR layer.

According to a second aspect of the present disclosure, a method is presented, the method comprising: implanting oxygen into a silicon substrate; based on the implanting, producing a first region of the silicon substrate proximal a surface of the silicon substrate, the first region including an implantation concentration that is stoichiometric; and further based on the implanting, producing a second region of the silicon substrate distal the surface of the silicon substrate, the second region including an implantation concentration that is under-stoichiometric; and annealing the silicon substrate thereby simultaneously generating: based on the first region, a silicon oxide region that is substantially devoid of free silicon or oxygen atoms; and based on the second region, a damaged region that includes defects imparted to a crystalline structure of the silicon substrate.

According to a third aspect of the present disclosure, a silicon substrate is presented, the silicon substrate comprising a buried oxide (BOX) layer and a trap rich (TL) layer, wherein: the BOX layer is provided by a region of silicon oxide that is formed by stoichiometric oxygen implantation into the silicon substrate followed by annealing of the silicon substrate, and the TL layer is provided by a damaged region that is formed, simultaneously to the BOX layer, by under-stoichiometric oxygen implantation into the silicon substrate followed by the annealing of the silicon substrate, the damaged region including defects imparted to a crystalline structure of the silicon substrate.

Further aspects of the disclosure are provided in the description, drawings and claims of the present application.

### BRIEF DESCRIPTION OF THE DRAWINGS

The accompanying drawings, which are incorporated into and constitute a part of this specification, illustrate one or more embodiments of the present disclosure and, together with the description of example embodiments, serve to explain the principles and implementations of the disclosure.

FIG. 1A shows a silicon-on-insulator (SOI) substrate.

FIG. 1B shows a silicon-on-insulator (SOI) substrate comprising a trap-rich layer.

FIG. 2A shows figures representative of process steps according to an embodiment of the present disclosure for simultaneous generation of a BOX layer and a trap-rich layer in a single substrate.

FIG. 2B shows figures representative of process steps according to another embodiment of the present disclosure for simultaneous generation of a BOX layer and a trap-rich layer in a single substrate having a layer of epitaxial silicon.

FIG. 3 shows a figure representative of a process step according to another embodiment of the present disclosure for extending a thickness of the trap-rich layer formed according to the process steps described in FIG. 2A.

FIG. 4 shows a substrate comprising localized BOX and trap-rich regions formed in a bulk substrate using the process steps of FIG. 2 and/or FIG. 3.

FIG. 5 is a process chart showing various steps of a method according to the present disclosure for simultaneous generation of a BOX layer and a trap-rich layer in a silicon substrate.

Like reference numbers and designations in the various drawings indicate like elements.

### DETAILED DESCRIPTION

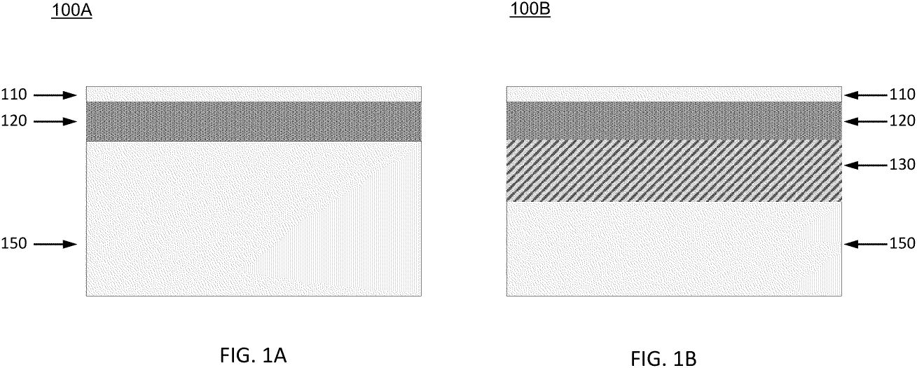

Teachings according to the present disclosure allow forming of the substrate (100B) of FIG. 1B from a single bulk silicon substrate/wafer. In other words, in contrast to some prior art processes, the BOX layer (120) and the trap-rich layer (130) are formed not by physically adding such layers atop a bulk silicon substrate, but rather by a process that includes oxygen (e.g., O₂) implantation followed by annealing which simultaneously generates/forms the layers (120, 130). Teachings according to the present disclosure may equally apply to regular silicon substrates and to high-resistivity silicon (HR-Si) substrates. It should be noted that in some RF applications, use of HR-Si substrate may be preferred for an increase RF performance of devices (e.g., transistors) formed on the substrate. Simultaneous generation of the BOX layer (120) and of the trap-rich layer (130) based on the methods according to present teachings can substantially reduce cost of the produced SOI substrate and therefore allow for a simpler and cheaper solution to parasitic-surface-conduction suppression in RF SOI and improved linearity as a consequence. As used herein, a high-resistivity silicon (HR-Si) substrate is a silicon substrate with a resistivity of 200 Ohm.cm or higher.

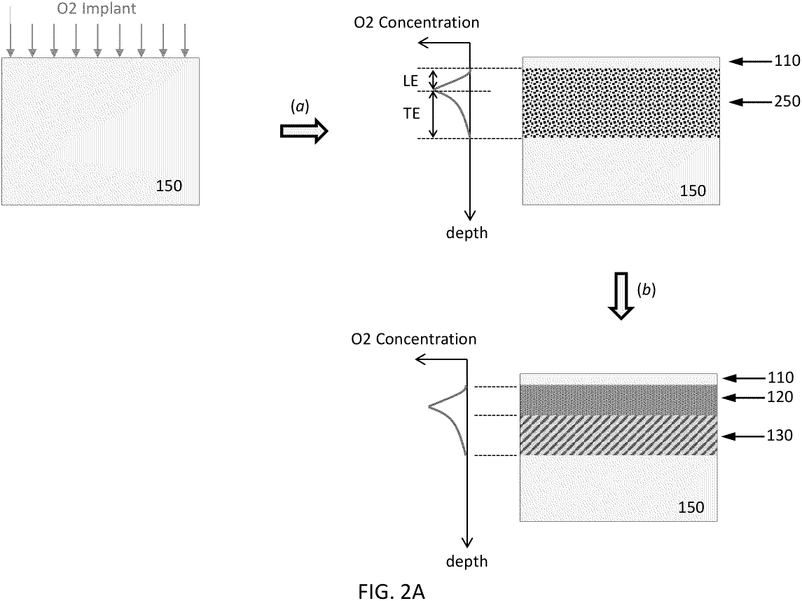

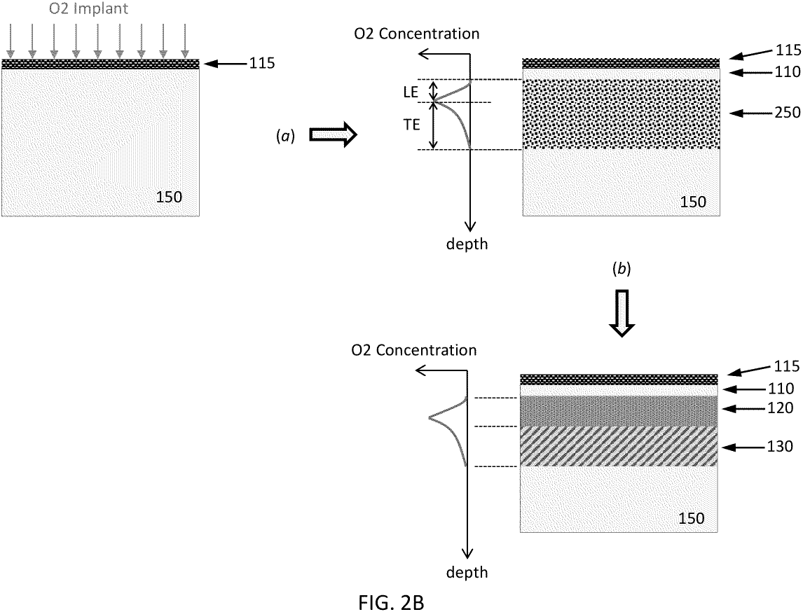

FIG. 2A shows figures representative of process steps according to an embodiment of the present disclosure for simultaneous generation of the BOX layer (120) and the trap-rich layer (130) in a single silicon substrate (150). According to an exemplary embodiment of the present disclosure, such process steps may be used to generate the BOX layer (120) having a thickness in a range from about few 10′s of nm (e.g., 20 nm) to about few 100′s of nm (e.g., 500 nm), and the trap-rich layer having a thickness in a range from about few 10′s of nm (e.g., 20 nm) to about few microns (e.g., 2-3 µm). As shown in the top left corner of FIG. 2A, the process starts (denoted as process step α) with oxygen (e.g., oxygen ions) implantation into a bulk silicon substrate (150). As shown in the top right corner of FIG. 2A, the oxygen implantation forms a damaged region (250) which includes oxygen atoms that may have damaged a portion of the crystalline structure of the substrate (150).

According to an embodiment of the present disclosure, process parameters for the implantation of the oxygen may be selected such as to produce in the damaged region (250) an oxygen concentration profile (i.e., depth profile) as shown in FIG. 2A. In particular, such oxygen concentration profile may include a leading-edge, LE, profile (e.g., leading-slope, leading-tail) that is shorter than a trailing-edge, TE, profile (e.g., trailing-slope, trailing-tail), wherein the LE profile and the TE profile join at a peak of the concentration profile. According to an embodiment of the present disclosure, the process parameters for the implantation of the oxygen may be further selected to produce/form the peak of the concentration profile at a (target) depth (from the top surface of the substrate 150) that corresponds to a region of the BOX layer (120).

According to another embodiment of the present disclosure, the process parameters for the implantation of the oxygen may be further selected such that the concentration of the implanted oxygen about the peak may be sufficient to form (e.g., via subsequent annealing, denoted as process step b in FIG. 2A) a region of silicon oxide (i.e., SiO2, stoichiometric region/layer, e.g., centered about the peak) that is substantially devoid of free silicon or oxygen atoms. As shown in the bottom right corner of FIG. 2A, such SiO2 region may provide the functionality of (e.g., forms) the BOX layer (120).

According to another embodiment of the present disclosure, the process parameters for the implantation of the oxygen may be further selected (e.g., via multiple/sequential oxygen implantations at different energy and/or dose) such that the concentration of the implanted oxygen in a region of the TE profile away from the peak may be under-stoichiometric and therefore produce, after annealing, a damaged region with trap-rich properties (e.g., trapping free carriers attracted to positively charged Si/SiO₂ interface provided by the bulk substrate 150 and the BOX layer 120, thereby limiting/preventing the PSC effect). As shown in the bottom right corner of FIG. 2A, such damaged region may provide the functionality of (e.g., forms) the trap-rich layer (130).

With continued reference to FIG. 2A, according to an embodiment of the present disclosure, process parameters for the annealing (i.e., process step b of FIG. 2A) may be selected such as to form in the region of the damaged region (250) about the peak concentration of the oxygen, the BOX layer (i.e., 120, SiO2 layer), thereby leaving a thin layer of Si (110) above the BOX layer (120) that may be used for forming of active devices (e.g., transistors). It should be noted that during the annealing step, free molecules/atoms of oxygen may diffuse deeper into the substrate (150) and below the BOX layer (120) into a region that becomes the trap-rich layer (130).

With further reference to FIG. 2A, according to another embodiment of the present disclosure, the process parameters for the annealing (i.e., process step b of FIG. 2A) may be further selected such as to form in a region of the damaged region (250) away from the peak concentration of the oxygen and along the region of the TE profile, a (post-annealing) damaged region with trap-rich properties that may provide the functionality of the trap-rich layer (130). It should be noted that such (post-annealing) damaged region may include oxygen atoms/molecules that were directly implanted in the region, or ones that have diffused into the region during the annealing (e.g., from region of the BOX layer).

As used herein, the term “damaged”, as used for example in the expressions “damaged region” or “damaged layer”, may refer to a region or a layer (e.g., 250 of FIG. 2A) of a silicon substrate (e.g., 150 of FIG. 2A) that includes defects imparted specifically to (locally) damage the crystalline structure of the silicon and trap free carriers. Such damage may extend from a partial damage wherein some of the crystalline structure is maintained outside the defects, to a full damage that is substantially devoid of a crystalline structure, and which may therefore be referred to an amorphous (damaged) structure. The defects imparted may include implanted or diffused oxygen, and/or random bonding of oxygen with silicon.

FIG. 2B shows figures representative of process steps according to another embodiment of the present disclosure for simultaneous generation of the BOX layer (120) and the trap-rich layer (130) in a single substrate (150) having a layer of epitaxial silicon (115). As can be clearly understood by a person skilled in the art, such process steps are similar to one described above with reference to FIG. 2A with the difference that the substrate (150) now includes the layer of epitaxial silicon (115). A person skilled in the art would clearly realize of benefits for including the layer (115) which are outside the scope of the present application. It should be noted that presence of the layer (115) may require adjustment to process parameters for the implantation step (a) and the annealing step (b).

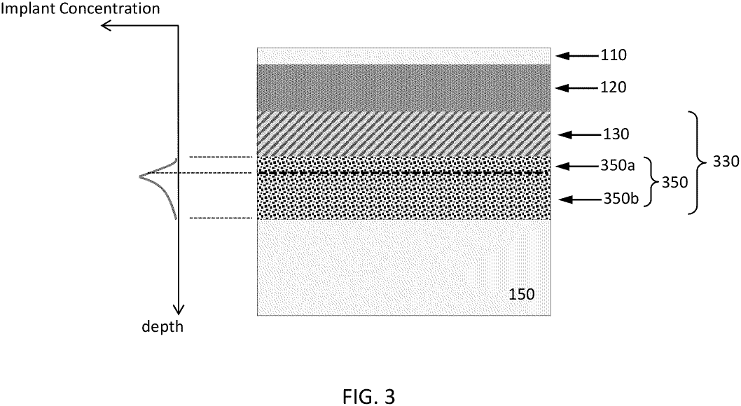

FIG. 3 shows a figure representative of a process step according to another embodiment of the present disclosure for extending a thickness of the trap-rich layer (130) formed according to the process steps described in FIG. 2A. As shown in FIG. 3, this includes implanting of additional elements (e.g., Ar, Ge, C, or other elements different from oxygen) at a depth below the layer (130). Accordingly, as shown in FIG. 3, a second damaged region (350), including the additional elements, is formed that extends below (deeper into the substrate 150) the layer (130). According to an embodiment of the present disclosure, the second damaged region (350) may include a first region (350a) that is (fully) included in the layer (130) and a second region (350b) that is immediately below and adjacent the layer (130). In other words, the second damaged region (350) may partially overlap the layer (130) and extend below the layer (130). Accordingly, the first region (350a) may include, in addition to the oxygen and Si elements, the additional elements. On the other hand, the second region (350b) may not include oxygen. As a result of the implanting of the additional elements and formation of the second damaged region (350), the effective trap-rich layer (330) of the SOI substrate shown in FIG. 3 is extended by the length of the second region (350b) when compared to the trap-rich layer (130) of the SOI substrate shown in FIG. 2.

With continued reference to FIG. 3, according to an embodiment of the present disclosure, process parameters for the implantation of the additional elements may be selected to produce/form a peak of the concentration profile of such elements at a (greater) depth (from the top surface of the substrate 150) that is below a depth of the peak concentration of oxygen described above with reference to, for example FIG. 2A. According to an exemplary non-limiting embodiment of the present disclosure, the peak concentration of the additional elements may be at a vicinity of an edge of the layer (130) as shown in FIG. 3 via a highlighted line. It should be noted that although not shown in FIG. 3, the implanting of the additional elements may be followed with an additional (e.g., optional) annealing step similar to one described above with reference to, for example, FIG. 2. Such additional annealing step may result in diffusion of some of the implanted elements further down into the substrate to further extend the depth of the second region (350b) beyond what is shown in FIG. 3, for a corresponding extension of the effective trap-rich layer (330). Furthermore, it should be noted that such step of implantation of additional elements followed by an optional step of annealing may be repeated to extend the depth (e.g., height) of the effective trap-rich layer (e.g., 330 of FIG. 3) progressively further thereby increasing the trapping effect.

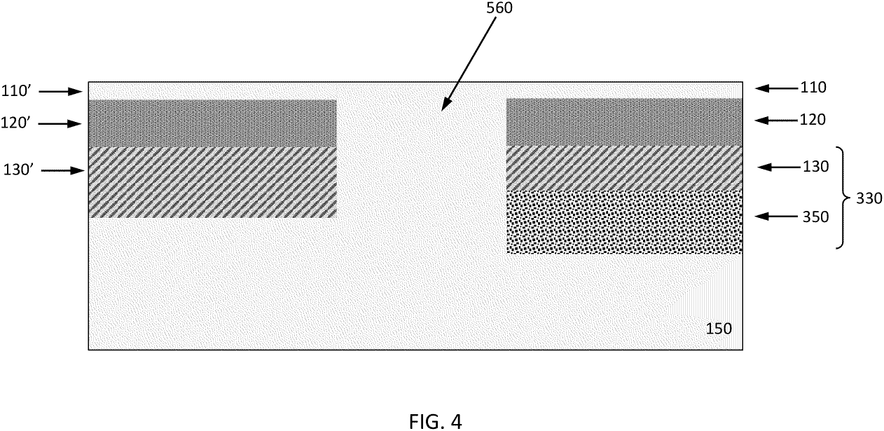

FIG. 4 shows a substrate comprising localized BOX and trap-rich regions formed in a bulk substrate (150) using the process steps described above with reference to FIG. 2 and/or FIG. 3. In particular, using such process steps, a first localized layered region (110, 120, 330) may be formed that is separate from a second localized layered region (110′, 120′, 130′). Masking, as known to a person skilled in the art, may be used to form a separation region (560) between the two layered regions that is devoid of BOX or trap rich regions. For example, during a first masking step that may include masking of the top surface of the separation region (560), the localized layers (110, 120, 330) and (110′, 120′, 130′) may be generated via the above described implanting and annealing steps with reference to FIG. 2A, and during a second masking step, that includes further masking of the top surface of the second localized layered region (110′, 120′, 130′), the localized layer (350) may be generated via the above described additional implanting and (optional) annealing steps with reference to FIG. 3. Other sequence of steps may be used for generating the substrate shown in FIG. 4, including, for example, first generating the first localized layered region (110, 120, 330) while masking the separation region (560) and the (targeted) second localized layered region (110, 120, 330), and then generating the second localized layered region (110′, 120′, 130′) while masking the separation region (560) and the first localized layered region (110, 120, 330). Such different sequence of steps may allow generation of localized layered area with independent control of depth (e.g., height) of the constituent layers.

Below is a table (Table 1) summarizing process steps according to the present teachings and in contrast to a prior art process steps used for forming an SOI substrate that does not include a trap-rich layer.

TABLE 1

| | | | |
|---|---|---|---|
| Process | Purpose & Characteristics | Present Teachings (PT) | Prior Art (PA) |
| 1^{st} Implantation (O2) | Purpose | Physical Implantation - towards forming a BOX and a damaged area below the BOX | Physical implantation - towards forming the BOX |
| | Dosage | A range of 1e15 to 1e18 at.cm-2 5e16-3e17 is typical | >1e17 |
| | Energy | 40 KeV-1MeV Most probably 50-200 KeV | >100 KeV |
| | O2 Concentration Profile | Long tail below the peak is desired (implantation and annealing is configured accordingly by applying more than one implant using the same species and same | Shortest possible tail below the peak is required |
| | | range of dose and energy i.e., tail-width control) | |
| 1^{st} Annealing | Purpose | (#1) Creating BOX: Follow up to physical implantation - Formation of SiO2 (O2 interacting w/ Si to form SiO2) (#2) Creating and preserving (“fixating or stabilizing”) a damaged area (trap rich area) at depths where O2 concentration is lower than the peak (“end of range”): preventing Si atoms from reforming a crystal structure (i.e., from healing back) - maintaining a “distorted” crystal | (#1) Creating BOX: Follow up to physical implantation - i.e., formation of SiO2 (O2 interacting w/ Si to form SiO2) - in PA, unlike PT, every O2 molecule is desired to form SiO2 |
| | Temperature | 950 °C - 1250 °C. with an optional short spike (<5 min) at a higher temperature above 1250 | Higher than PT (> 1300 °C.) |
| | Time | 30 min - 6.0 hours | Similar |
| | Atmospheric Environment | N/A | N/A |
| 2nd Implantation (Other species) | Purpose | Further extend the depth of the damaged area below the BOX, i.e., the trap rich area. The overall damaged area has areas of mixed concentration of O2 and the additional-species; and adjacent areas with substantial concentration of the additional species only. | N/A |
| | Dosage | Range: 1e14-1e18 at.cm-2 | N/A |
| | Energy | 40 KeV-1 MeV Most probably 50-200 KeV | N/A |
| | 2^{nd} Species Concentration Profile | Long tail is desirable for deeper damaged area (→ deeper trap rich area) 2^{nd} implantation and annealing are configured accordingly; possibly 1^{st} implantation and 1^{st} annealing as well in combination but not necessarily) | |
| 2nd Annealing (optional) | Temperature | > 800 °C. | N/A |
| | Time | > 10 min | N/A |
| | Atmospheric Environment | N/A | N/A |

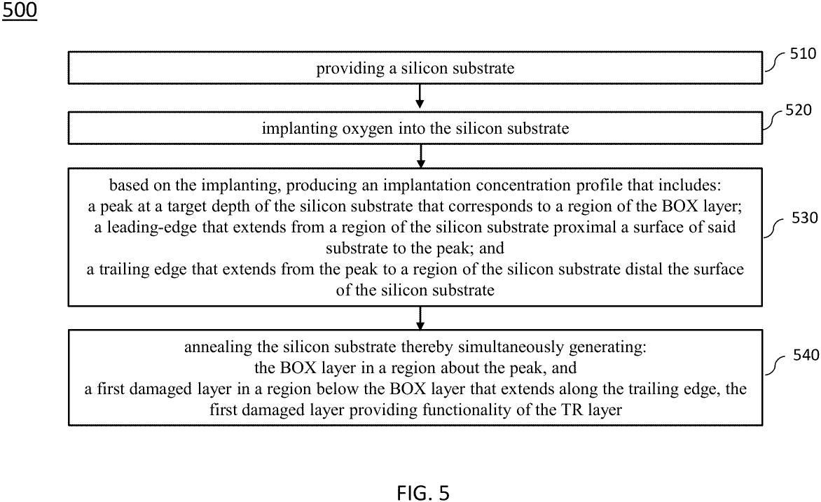

FIG. 5 is a process chart (500) showing various steps of a method according to the present disclosure for simultaneous generation of a BOX layer and a trap-rich layer in a silicon substrate. As shown in FIG. 5 such steps comprise: providing a silicon substrate, per step (510); implanting oxygen into the silicon substrate, per step (520); based on the implanting, producing an implantation concentration profile that includes: a peak at a target depth of the silicon substrate that corresponds to a region of the BOX layer; a leading-edge that extends from a region of the silicon substrate proximal a surface of said substrate to the peak; and a trailing edge that extends from the peak to a region of the silicon substrate distal the surface of the silicon substrate, per step (530); and annealing the silicon substrate thereby simultaneously generating: the BOX layer in a region about the peak, and a first damaged layer in a region below the BOX layer that extends along the trailing edge, the first damaged layer providing functionality of the TR layer, per step (540).

The term “MOSFET”, as used in this disclosure, includes any field effect transistor (FET) having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies such as bipolar, BiCMOS, LDMOS, BCD, GaAs HBT, GaN HEMT, GaAs pHEMT, and MESFET technologies. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

Circuits and devices in accordance with the present invention may be used alone or in combination with other components, circuits, and devices. Embodiments of the present invention may be fabricated as integrated circuits (ICs), which may be encased in IC packages and/or in modules for ease of handling, manufacture, and/or improved performance. In particular, IC embodiments of this invention are often used in modules in which one or more of such ICs are combined with other circuit blocks (e.g., filters, amplifiers, passive components, and possibly additional ICs) into one package. The ICs and/or modules are then typically combined with other components, often on a printed circuit board, to form part of an end product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

1. A method for simultaneous generation of a buried oxide (BOX) layer and a trap-rich (TR) layer in a silicon substrate, the method comprising:
providing a silicon substrate;
implanting oxygen into the silicon substrate;
based on the implanting, producing an implantation concentration profile that includes:
a peak at a target depth of the silicon substrate that corresponds to a region of the BOX layer;
a leading-edge that extends from a region of the silicon substrate proximal a surface of said substrate to the peak; and
a trailing edge that extends from the peak to a region of the silicon substrate distal the surface of the silicon substrate; and
annealing the silicon substrate thereby simultaneously generating:
the BOX layer in a region about the peak, and
a first damaged layer in a region below the BOX layer that extends along the trailing edge, the first damaged layer providing functionality of the TR layer.

2. The method according to claim 1, wherein:
the implantation concentration profile in the region about the peak is stoichiometric, and
the implantation concentration profile in the region that extends along the trailing edge and away from the peak is under-stoichiometric.

3. The method according to claim 1, wherein:
the BOX layer is provided by a region of silicon oxide that is substantially devoid of free silicon or oxygen atoms, and
the first damaged layer is provided by defects imparted to a crystalline structure of the silicon substrate.

4. The method according to claim 3, wherein:
the defects imparted to the crystalline structure include one or more of: a) implanted oxygen, b) diffused oxygen, or c) random bonding of oxygen with silicon.

5. The method according to claim 1, wherein:
a thickness of the BOX layer is in a range from 20 nm to 500 nm, and
a thickness of the TL layer is in a range from 20 nm to 3 µm.

6. The method according to claim 1, further comprising:
based on the annealing, further generating a thin layer of silicon above the BOX layer, the thin layer of silicon provided by a region of the silicon substrate between the surface of the silicon substrate and a start of the leading-edge.

7. The method according to claim 6, further comprising:
forming at least one transistor in the thin layer of silicon, the at least one transistor configured for operation as a radio frequency (RF) device.

8. The method according to claim 1, further comprising:
further implanting an additional element different from oxygen into the silicon substrate;
based on the further implanting, producing an additional implantation concentration profile that includes:
an additional peak at a target depth of the silicon substrate that corresponds to a region of the first damaged layer;
an additional leading-edge that extends from a region of the first damaged layer to the additional peak; and
an additional trailing edge that extends from the additional peak to a region of the silicon substrate below the first damaged layer; and
based on the producing of the additional concentration profile, generating a second damaged layer through an extension of the additional trailing edge.

9. The method according to claim 8, wherein:
the second damaged layer effectively increases a depth for the functionality of the TR layer.

10. The method according to claim 8, further comprising:
an additional annealing of the silicon substrate.

11. The method according to claim 1, wherein:
the silicon substrate is a high resistivity silicon substrate.

12. The method according to claim 11, wherein:
the high resistivity is provided by a resistivity of the silicon substrate that is equal to or higher than 200 Ohm.cm.

13. The method according to claim 1, wherein:
the trailing-edge of the implantation concentration profile is longer that the leading-edge of the implantation concentration profile.

14. The method according to claim 1, further comprising:
masking a top surface of the silicon substrate prior to the implanting and the annealing, thereby generating localized layered structures separated by a separation region that exclusively contains a crystalline structure of the silicon substrate, wherein each of the localized layered structures comprises a localized region of the BOX layer and a localized region of the first damaged layer.

15. The method according to claim 1, wherein:
the providing of the silicon substrate includes providing a layer of epitaxial silicon arranged atop the surface of the silicon substrate.

16. A silicon on insulator wafer, comprising:
a silicon substrate comprising a buried oxide (BOX) layer and a trap rich (TL) layer, wherein the BOX layer and the TL layer are simultaneously generated according to the method of claim 1.

17. A method, comprising:
implanting oxygen into a silicon substrate;
based on the implanting, producing a first region of the silicon substrate proximal a surface of the silicon substrate, the first region including an implantation concentration that is stoichiometric; and
further based on the implanting, producing a second region of the silicon substrate distal the surface of the silicon substrate, the second region including an implantation concentration that is under-stoichiometric; and
annealing the silicon substrate thereby simultaneously generating:
based on the first region, a silicon oxide region that is substantially devoid of free silicon or oxygen atoms; and
based on the second region, a damaged region that includes defects imparted to a crystalline structure of the silicon substrate.

18. The method according to claim 17, wherein:
the defects imparted to the crystalline structure include one or more of: a) implanted oxygen, b) diffused oxygen, or c) random bonding of oxygen with silicon.

19. The method according to claim 17, wherein:
a thickness of the first region is in a range from 20 nm to 500 nm, and
a thickness of the second region is in a range from 20 nm to 3 µm.

20. The method according to claim 17, wherein:
the first region provides a functionality of a buried oxide (BOX) layer, and
the second region provides a functionality of a trap-rich (TR) layer.

21. A silicon on insulator wafer, comprising:
a silicon substrate comprising a buried oxide (BOX) layer and a trap rich (TL) layer, wherein the BOX layer and the TL layer are simultaneously generated according to the method of claim 20.

22. A silicon on insulator wafer, comprising:
a silicon substrate comprising a buried oxide (BOX) layer and a trap rich (TL) layer, wherein:
the BOX layer is provided by a region of silicon oxide that is formed by stoichiometric oxygen implantation into the silicon substrate followed by annealing of the silicon substrate, and
the TL layer is provided by a damaged region that is formed, simultaneously to the BOX layer, by under-stoichiometric oxygen implantation into the silicon substrate followed by the annealing of the silicon substrate, the damaged region including defects imparted to a crystalline structure of the silicon substrate.
